(19) United States
(12) Patent Application Publication
(10) Pub. No.: US 2016/0268439 A1
(43) Pub. Date: Sep. 15, 2016

(54) NON-VOLATILE MEMORY DEVICE

(71) Applicant: Kabushiki Kaisha Toshiba, Minato-ku (JP)

(72) Inventors: Wataru SAKAMOTO, Yokkaichi (JP); Tatsuya KATO, Yokkaichi (JP); Fumitaka ARAI, Yokkaichi (JP)

(73) Assignee: Kabushiki Kaisha Toshiba, Minato-ku (JP)

(21) Appl. No.: 14/836,094

(22) Filed: Aug. 26, 2015

Related U.S. Application Data
(60) Provisional application No. 62/130,912, filed on Mar. 10, 2015.

(51) Int. Cl. H01L 29/788; H01L 27/115

(52) U.S. Cl. CPC H01L 29/7887; H01L 27/11529; H01L 27/11531

(57) ABSTRACT

A non-volatile memory device includes a first semiconductor body extending in a first direction and a second semiconductor body arranged side by side with the first semiconductor body. The second semiconductor body extends in the first direction. The device further includes a first electrode between the first semiconductor body and the second semiconductor body and extending in a second direction crossing the first direction, a first charge storage layer between the first electrode and the first semiconductor body, and a second charge storage layer between the first electrode and the second semiconductor body.

### CROSS-REFERENCE TO RELATED APPLICATIONS

This application is based upon and claims the benefit of priority from U.S. Provisional Patent Application 62/130,912 filed on Mar. 10, 2015; the entire contents of which are incorporated herein by reference.

### FIELD

Embodiments are generally related to a non-volatile memory device.

### BACKGROUND

A non-volatile memory device having a three-dimensional memory cell array have been developed to enlarge the memory capacity. For instance, a NAND semiconductor memory device comprises a plurality of NAND strings, and the memory capacity is enlarged by stacking NAND strings. However, each NAND string includes memory cells arrayed on a channel layer, and select transistors placed on both sides of the memory cells. The manufacturing steps for stacking such a NAND string may increase the manufacturing cost. Thus, there is demand for reducing the manufacturing steps of the non-volatile memory device having the three-dimensional memory cell array.

### BRIEF DESCRIPTION OF THE DRAWINGS

FIG. 1 is a block diagram schematically showing a structure of a non-volatile memory device according to a first embodiment;

FIG. 2 is a schematic plan view showing a memory cell array of the non-volatile memory device according to the first embodiment;

FIG. 3 is a schematic cross-sectional view showing the memory cell array of the non-volatile memory device according to the first embodiment;

FIG. 4 is schematic cross-sectional view showing another memory cell array of a non-volatile memory device according to the first embodiment;

FIGS. 5A and 5B are schematic cross-sectional views showing peripheral circuit elements according to the first embodiment;

FIGS. 6A to 10B are schematic cross-sectional views showing a manufacturing process of the memory cell array according to the first embodiment;

FIG. 11 is a schematic cross-sectional view showing a memory cell array according to a variation of the first embodiment; and

FIG. 12 is a schematic plan view showing a memory cell array of a non-volatile memory device according to a second embodiment.

### DETAILED DESCRIPTION

According to an embodiment, a non-volatile memory device includes a first semiconductor body extending in a first direction and a second semiconductor body arranged side by side with the first semiconductor body. The second semiconductor body extends in the first direction. The device further includes a first electrode between the first semiconductor body and the second semiconductor body and extending in a second direction crossing the first direction, a first charge storage layer between the first electrode and the first semiconductor body, and a second charge storage layer between the first electrode and the second semiconductor body.

Embodiments will now be described with reference to the drawings. The same portions inside the drawings are marked with the same numerals; a detailed description is omitted as appropriate; and the different portions are described. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

There are cases where the dispositions of the components are described using the directions of XYZ axes shown in the drawings. The X-axis, the Y-axis, and the Z-axis are orthogonal to each other. Hereinbelow, the directions of the X-axis, the Y-axis, and the Z-axis are described as an X-direction, a Y-direction, and a Z-direction. Also, there are cases where the Z-direction is described as upward and the direction opposite to the Z-direction is described as downward.

### FIRST EMBODIMENT

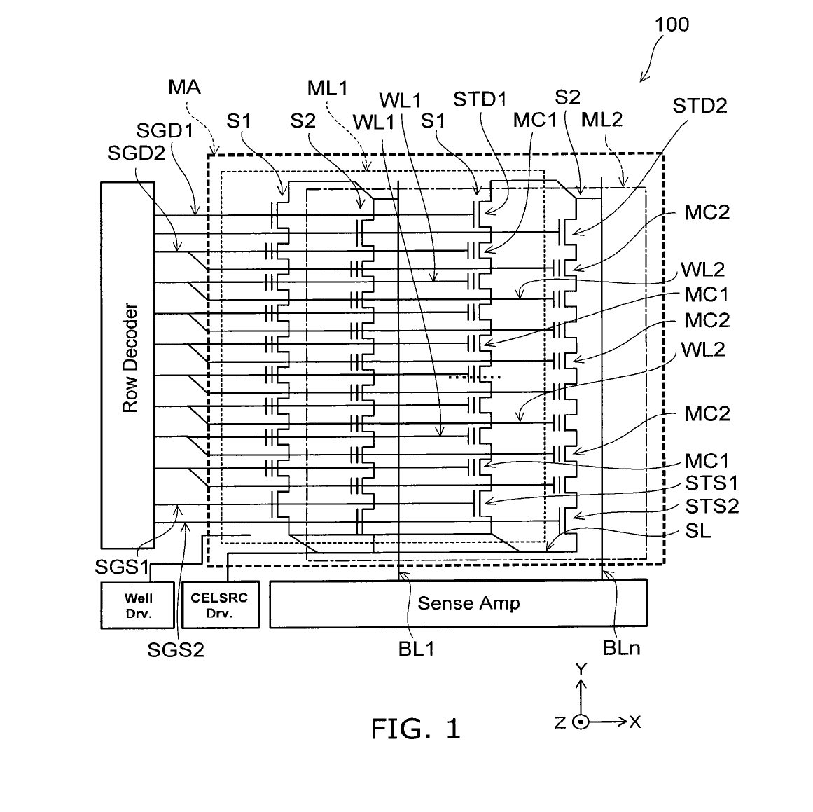

FIG. 1 is a block diagram schematically showing a non-volatile memory device 100 according to a first embodiment. The non-volatile memory device 100 is a NAND semiconductor memory device, for example. The non-volatile memory device 100 includes a memory area MA and a peripheral circuit area on a chip surface thereof. The peripheral circuit area is provided around the memory area MA, for example.

The memory area MA includes a memory layer ML1 and a memory layer ML2. The memory layer ML2 is provided on the memory layer ML1. The memory layer ML1 includes NAND strings S1. The memory layer ML2 includes NAND strings S2. The NAND strings S1, S2 are arranged side by side in the X-direction in the memory layers ML1 and ML2, respectively. Each NAND string S2 is provided on the NAND string S1, i.e. NAND strings S1 and S2 are stacked in the Z-direction perpendicular to the substrate.

Each of the NAND strings S1 and S2 include a plurality of memory cells MC, a select transistor STD, and a select transistor STS. Memory cells MC are disposed in line in the Y-direction between the select transistor STD and the select transistor STS. A memory cell MC of the NAND string S2 is placed on a memory cell MC of the NAND string S1. A group of NAND strings S1 and S2 arranged side by side in the X-direction is referred to as one block. Although not shown herein, a plurality of blocks are repetitively disposed in the Y-direction, and form the entire memory cell array.

The peripheral circuit area includes a row decoder, a sense amplifier (Sense Amp), a source line driver (CELSRC), a well driver and the like. The row decoder is electrically connected to memory cells MC via word lines WL. The sense amplifier is electrically connected to the drain of the select transistor STD via a bit line BL. The source line driver is electrically connected to the source of the select transistor STS via a source line SL. The source line driver adjusts the source potential of the select transistor STS. For example, the well driver is electrically connected to a p-type well region in the substrate. The well driver adjusts the potential of the p-type well region.

As shown in FIG. 1, the word line WL extends in the X-direction. The word line WL is electrically connected to a memory cell MC of each NAND string. A word line WL1 connected to memory cells MC1 in the memory layer ML1 may be electrically connected to a word line WL2 connected to memory cells MC2 in the memory layer ML2. That is, each memory cell MC1 may share a word line WL with a memory cell MC2 thereabove. The word line WL is also shared over blocks disposed in the Y-direction.

Bit lines BL extend in the Y-direction along the NAND strings S1 and S2. Each bit line BL is electrically connected to both the drain of the select transistor STD1 in the memory layer ML1 and the drain of the select transistor STD2 in the memory layer ML2. That is, the NAND string S2 of the memory layer ML1 shares the bit line BL with the NAND string S1 therebelow.

The source line SL extends in the X-direction, in which the NAND strings S1 and S2 are arranged side by side. The source line SL is electrically connected to the source of the select transistor STS of each NAND string. That is, the source line SL is shared by a plurality of NAND strings S1 and S2. The source line is also shared over blocks arranged in the Y-direction.

The row decoder further controls the select transistors of NAND strings S1 and S2 via selecting gates SGD1, SGD2, SGS1, and SGS2. A selecting gate SGD1 extends in the X-direction. The row decoder turns select transistors STD1 on and off via the selecting gate SGD1. A selecting gate SGD2 extends in the X-direction. The row decoder turns select transistors STD2 on and off via the selecting gate SGD2. A selecting gate SGS1 extends in the X-direction. The row decoder turns select transistors STS1 on and off via the selecting gate SGS1. A selecting gate SGS2 extends in the X-direction. The row decoder turns the select transistor STS2 on and off via the selecting gate SGS2. The select transistors STD and STS switch the electrical conduction on and off between the bit line BL and the source line SL. Thus, the row decoder selects one of the NAND strings S1 and S2 for each bit line BL using the select transistors STD and STS.

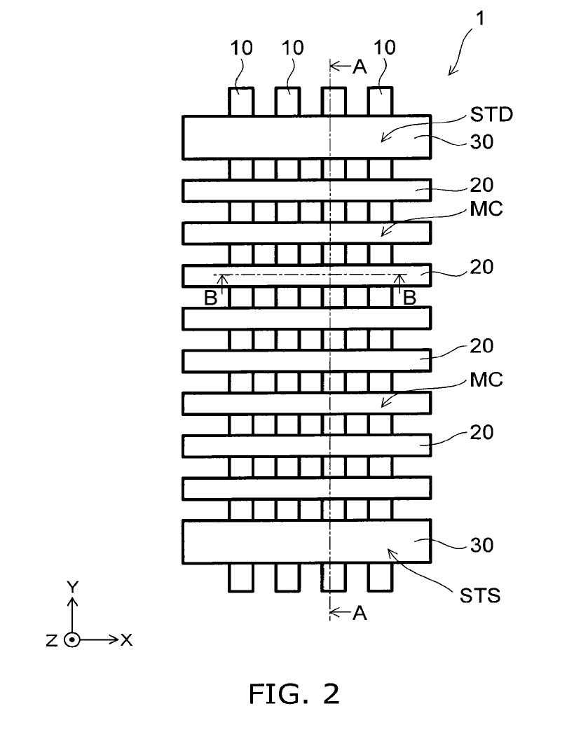

FIG. 2 is a schematic plan view showing a memory cell array 1 of the non-volatile memory device according to the first embodiment. FIG. 2 shows a layout of a semiconductor (hereinafter, channel body 10), an electrode (hereinafter, word line 20), and a pair of selecting gates 30 in each of the memory layers ML1 and ML2.

NAND strings S1 and S2 include channel bodies 10. Each channel body 10 is provided like a stripe extending in the Y-direction. The channel bodies 10 are arranged side by side in the X-direction. The word lines 20 extend in the X-direction. A memory cell MC is provided at a crossing portion of the channel body 10 and the word line 20. A selecting gate 30 extends in the X-direction on both sides of word lines 20. The select transistor STD is provided in the crossing portion of the channel body 10 and one of selecting gates 30. The select transistor STS is provided at a crossing portion of the channel body 10 and the other of selecting gate 30.

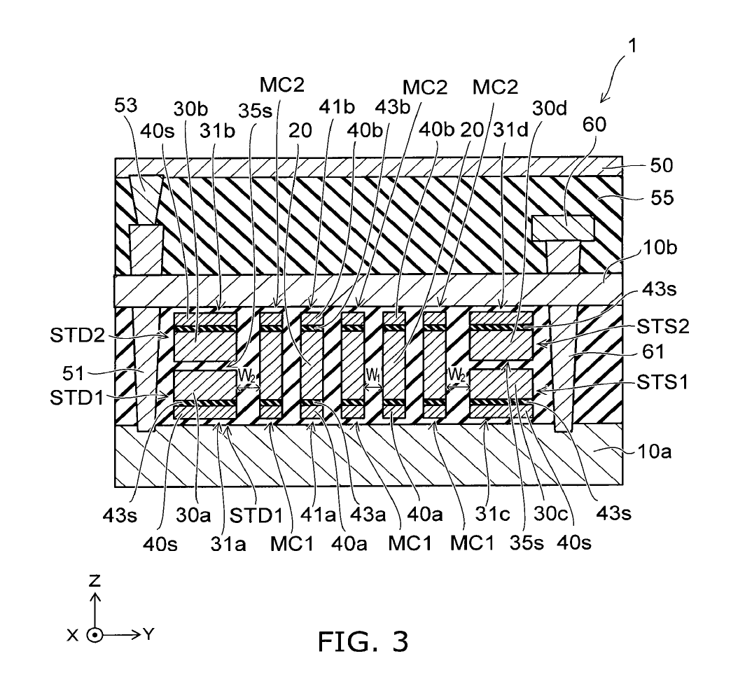

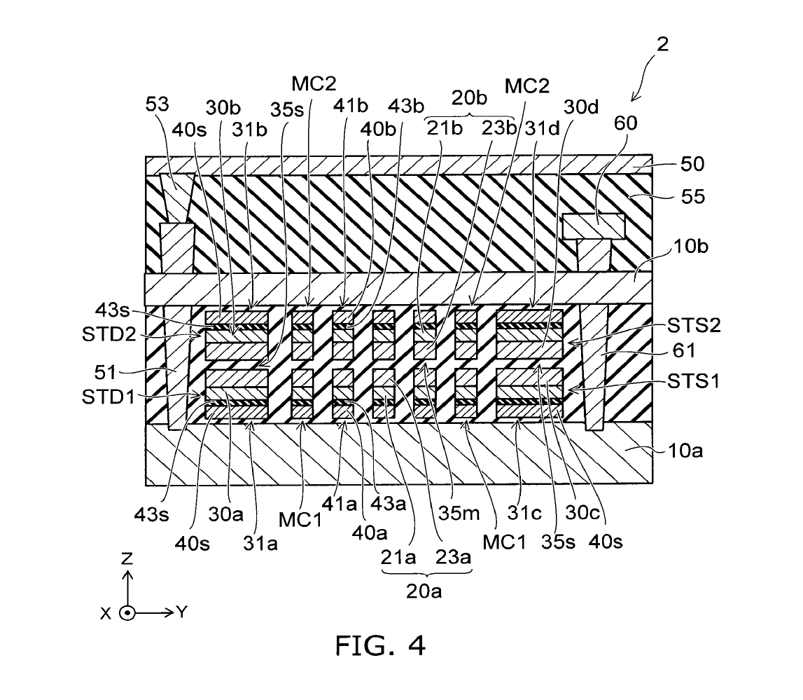

FIG. 3 is a schematic cross-sectional view showing the memory cell array 1 according to the first embodiment. FIG. 4 is a schematic cross-sectional view showing a memory cell array 2 according to a variation of the first embodiment.

The memory cell array 1 shown in FIG. 3 includes a first semiconductor (hereinafter, channel body 10a) and a second semiconductor (hereinafter, channel body 10b). The channel bodies 10a and 10b are provided on an underlying layer, and extend in a first direction (hereinafter, Y-direction) parallel to a surface of the underlying layer. The underlying layer is, for example, a semiconductor substrate (not shown). The channel body 10b is stacked on the channel body 10a.

The memory cell array 1 includes first electrodes (hereinafter, word lines 20), first charge storage layers (hereinafter, charge storage layers 40a), and second charge storage layers (hereinafter, charge storage layers 40b). The word lines 20, the charge storage layers 40a and 40b are disposed between the channel body 10a and the channel body 10b.

The memory cell array 1 includes memory cells MC1 and memory cells MC2 between the channel body 10a and the channel body 10b. Each memory cell MC1 includes a charge storage layer 40a. The memory cells MC1 are arranged in line in the Y-direction along the channel body 10a. Each memory cell MC2 includes a charge storage layer 40b. The memory cells MC2 are arranged in line in the Y-direction along the channel body 10b. A pair of memory cells MC1 and MC2 shares the word line 20. The word lines 20 extend in a second direction (hereinafter, X-direction) crossing the Y-direction. The word lines 20 are made of e.g. tungsten.

The charge storage layer 40a is provided between the channel body 10a and the word line 20. The charge storage layer 40b is provided between the channel body 10b and the word line 20. The charge storage layers 40a and 40b may be a conductive floating gate. The charge storage layers 40a and 40b may include, for example, one of polysilicon, titanium nitride, and tantalum nitride. The charge storage layers 40a and 40b may be an insulating film such as silicon nitride film.

The memory cell MC1 includes an insulative tunneling layer 41a and an insulative blocking layer 43a. The insulative tunneling layer 41a is provided between the channel body 10a and the charge storage layer 40a. The insulative blocking layer 43a is provided between the charge storage layer 40a and the word line 20a. The memory cell MC2 includes an insulative tunneling layer 41b and an insulative blocking layer 43b. The insulative tunneling layer 41b is provided between the channel body 10b and the charge storage layer 40b. The insulative blocking layer 43b is provided between the charge storage layer 40b and the word line 20b. For instance, the insulative blocking layers 43a and 43b include a material, so-called high-k film that has higher permittivity than the insulative tunneling layers 41a and 41b.

Each word line 20 may include, for example, one of titanium nitride (TIN), tantalum nitride (TaN), tungsten nitride (WN), p-type polysilicon, and n-type polysilicon in the portion in contact with the insulative blocking layer 43a and the portion in contact with the insulative blocking layer 43b.

The memory cell array 1 includes a first conducting body (hereinafter, contact plug 51) extending in the Z-direction. The contact plug 51 electrically connects the channel body 10a to the channel body 10b. The memory cell array 1 includes a select transistor STD1 between the contact plug 51 and the memory cells MC1, and a select transistor STD2 between the contact plug 51 and the memory cells MC2.

The select transistor STD1 includes a first selecting gate (hereinafter, selecting gate 30a) and a first gate insulating film (hereinafter, gate insulating film 31a). The selecting gate 30a is disposed between the contact plug 51 and a word line 20 at one end of the word lines 20. The gate insulating film 31a is provided between the channel body 10a and the selecting gate 30a.

The select transistor STD2 includes a second selecting gate (hereinafter, selecting gate 30b) and a second gate insulating film (hereinafter, gate insulating film 31b). The selecting gate 30b is disposed between the contact plug 51 and the word line 20 at the one end of the word lines 20. The selecting gate 30b is provided on the selecting gate 30a via a first insulating layer (hereinafter, insulating layer 35s). The gate insulating film 31b is provided between the channel body 10b and the selecting gate 30b.

The select transistor STD1 may include a conductive layer 40s and an insulating film 43s between the gate insulating film 31a and the selecting gate 30a. The select transistor STD2 may also include a conductive layer 40s and an insulating film 43s between the gate insulating film 31b and the selecting gate 30b. The contact plug 51 is electrically connected to the drains of the select transistors STD1 and STD2.

The conductive layer 40s includes the same structure and the same material as the charge storage layer 40a or the charge storage layer 40b. The insulating film 43s includes the same structure and the same material as the insulative blocking layer 43a or 43b. The insulating layer 35s is, for example, a silicon oxide film. Alternatively, the insulating layer 35s may have a multilayer structure that includes a silicon oxide film and a silicon nitride film.

The memory cell array 1 includes a second conducting body (hereinafter, contact plug 61) extending in the Z-direction.

The contact plug 61 electrically connects the channel body 10a to the channel body 10b. The memory cells MC1, MC2 and the select transistors STD1, STD2 are disposed between the contact plug 51 and the contact plug 61. Furthermore, the memory cell array 1 includes a select transistor STS1 between the contact plug 61 and the memory cells MC1, and a select transistor STS2 between the contact plug 61 and the memory cells MC2.

The select transistor STS1 includes a selecting gate 30c and a gate insulating film 31c. The selecting gate 30c is disposed between the contact plug 61 and a word line 20 at the other end of the word lines 20. The gate insulating film 31c is provided between the channel body 10a and the selecting gate 30c.

The select transistor STS2 includes a selecting gate 30d and a gate insulating film 31d. The selecting gate 30d is disposed between the contact plug 61 and the word line 20 at the other end of the word lines 20. The gate insulating film 31d is provided between the channel body 10b and the selecting gate 30d.

The spacing W₂ between one of the select transistors STS and STD and the memory cell MC adjacent thereto is larger than the spacing W₁ between two adjacent memory cells MC in the Y-direction. A difference between the spacing W₂ and the spacing W₁ is preferably 10 nanometers or less.

The memory cell array 1 further includes a bit line 50 and a source line 60. The bit line 50 is provided on an insulating layer 55 that covers the channel body 10b. The bit line 50 extends in the Y-direction. The bit line 50 is electrically connected to the channel bodies 10a and 10b via the contact plugs 51 and 53. The source line 60 extends in the X-direction in the insulating layer 55. The source line 60 is electrically connected to the channel bodies 10a and 10b via the contact plug 61.

The memory cell array 2 shown in FIG. 4 further includes second insulating layers (hereinafter, insulating layers 35m) vertically separating each word line 20. The word line 20 includes a first portion (hereinafter, word line 20a) and a second portion (hereinafter, word line 20b).

The word line 20a is electrically connected to the word line 20b in a portion not shown (see FIG. 1). The insulating layers 35m is formed simultaneously with insulating layers 35s between the select transistors STD1 and STD2 and between the select transistors STS1 and STS2. The insulating layers 35m are silicon oxide films, for example. Alternatively, each insulating layer 35m may have a multilayer structure that includes a silicon oxide film and a silicon nitride film. In this specification, for instance, there is the case where the word lines 20a and 20b are collectively referred to as word lines 20. Other elements are also referred collectively in the same manner.

The memory cell array 2 includes memory cells MC1 and memory cells MC2 between the channel body 10a and the channel body 10b. The memory cell MC1 includes the charge storage layer 40a. The memory cells MC1 are arranged in the Y-direction along the channel body 10a. The memory cell MC2 includes the charge storage layer 40b. The memory cells MC2 are arranged in the Y-direction along the channel body 10b. The charge storage layer 40a is provided between the channel body 10a and the word line 20a. The charge storage layer 40b is provided between the channel body 10b and the word line 20b.

The memory cell MC1 includes an insulative tunneling layer 41a and an insulative blocking layer 43a. The insulative tunneling layer 41a is provided between the channel body 10a and the charge storage layer 40a. The insulative blocking layer 43a is provided between the charge storage layer 40a and the word line 20a. The memory cell MC2 includes an insulative tunneling layer 41b and an insulative blocking layer 43b. The insulative tunneling layer 41b is provided between the channel body 10b and the charge storage layer 40b. The insulative blocking layer 43b is provided between the charge storage layer 40b and the word line 20b.

The word line 20a includes a first layer 21a and a second layer 23a. The first layer 21a is in contact with the insulative blocking layer 43a. The word line 20b includes a first layer 21b and a second layer 23b. The first layer 21b is in contact with the insulative blocking layer 43b.

The first layer 21 is preferably made of a material that increases the potential energy difference between the word line 20 and the insulative blocking layer 43. In other words, the first layer 21 has a larger work function than the second layer 23, for example. This can suppress a carrier movement through the insulative blocking layer 43 from the word line 20 to the charge storage layer 40, and reduce the voltage applied between the channel body 10 and the word line 20 for data write or erasure in the charge storage layer 40. The second layers 23a and 23b are tungsten layers, for example.

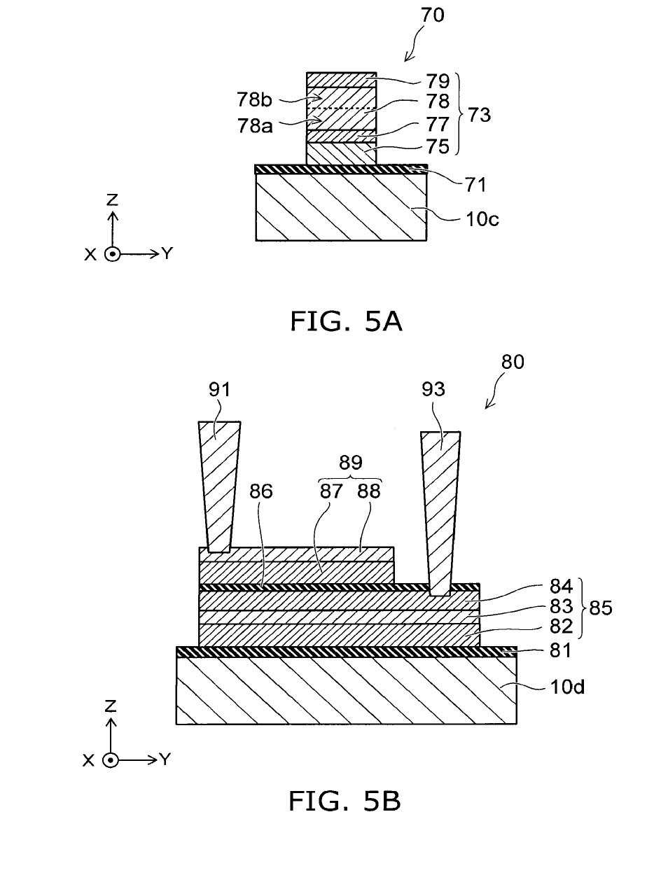

FIGS. 5A and 5B are schematic sectional views showing a peripheral circuit element of the non-volatile memory device 100 according to the first embodiment. FIG. 5A is a schematic view showing a cross section of a transistor element 70. FIG. 5B is a schematic view showing a cross section of a capacitor element 80.

The transistor element 70 shown in FIG. 5A includes a gate insulating film 71 and a gate electrode 73 provided on a third semiconductor (hereinafter, channel body 10c). The channel body 10c may be a portion of the channel body 10a extended in the Y-direction, for example. Alternatively, the channel body 10c may be arranged side by side with the channel body 10a in the X-direction.

The gate electrode 73 has a structure in which a conductive layer 75, a first layer 77, a second layer 78, and a third layer 79 are stacked, for example. The second layer 78 includes a first portion 78a and a second portion 78b, for example.

The conductive layer 75 is formed, for example, simultaneously with the charge storage layer 40a. The first layer 77 and the first portion 78a of the second layer 78 are formed, for example, simultaneously with the word line 20a. The second portion 78b of the second layer 78 and the third layer 79 are formed, for example, simultaneously with the word line 20b. That is, the gate electrode 73 has a structure in which the insulative blocking layer 43a and the insulating layer 35m are removed from the multilayer body of the charge storage layer 40a, the word line 20a, and the word line 20b. The total film thickness of the word line 20a and the word line 20b is the same as the total film thickness of the first layer 77, the second layer 78, and the third layer 79.

In this specification, the term “same” is not limited to being exactly the same, but may allow difference in the composition and thickness distributions of the materials due to the manufacturing process of the memory cell array 1.

The capacitor element 80 shown in FIG. 5B includes, for example, a third electrode (hereinafter, electrode 85), a dielectric film 86, and a fourth electrode (hereinafter, electrode 89) provided on the channel body 10d. The channel body 10d may be a portion of the channel body 10a extended in the Y-direction. Alternatively, the channel body 10d may be arranged side by side with the channel body 10a in the X-direction.

As shown in FIG. 5B, the capacitor element 80 may include an insulating film 81 between the channel body 10d and the electrode 85. The insulating film 81 is, for example, formed simultaneously with the insulative tunneling layer 41a.

The electrode 85 has a structure in which a conductive layer 82, a first layer 83, and a second layer 84 are stacked, for example. The electrode 89 includes a third layer 87 and a fourth layer 88. The third layer 87 is formed on the dielectric film 86. The fourth layer 88 is formed on the third layer 87.

The conductive layer 82 is, for example, formed simultaneously with the charge storage layer 40a. The first layer 83 and the second layer 84 are, for example, formed simultaneously with the word line 20a. The dielectric film 86 is, for example, formed simultaneously with the insulating layers 35s and 35m. The third layer 87 and the fourth layer 88 are, for example, formed simultaneously with the word line 20b.

That is, the electrode 85 has a structure in which the insulative blocking layer 43a is removed from the multilayer body of the charge storage layer 40a and the word line 20a. The electrode 85 includes the same material as the charge storage layer 40a and the word line 20a. The electrode 89 has the same structure and includes the same material as the word line 20b. The total film thickness of the first layer 83 and the second layer 84 is the same as the film thickness of the word line 20a. The film thickness of the electrode 89 is the same as the film thickness of the word line 20b. The dielectric film 86 includes the same material and has the same structure as the insulating layers 35s, 35m.

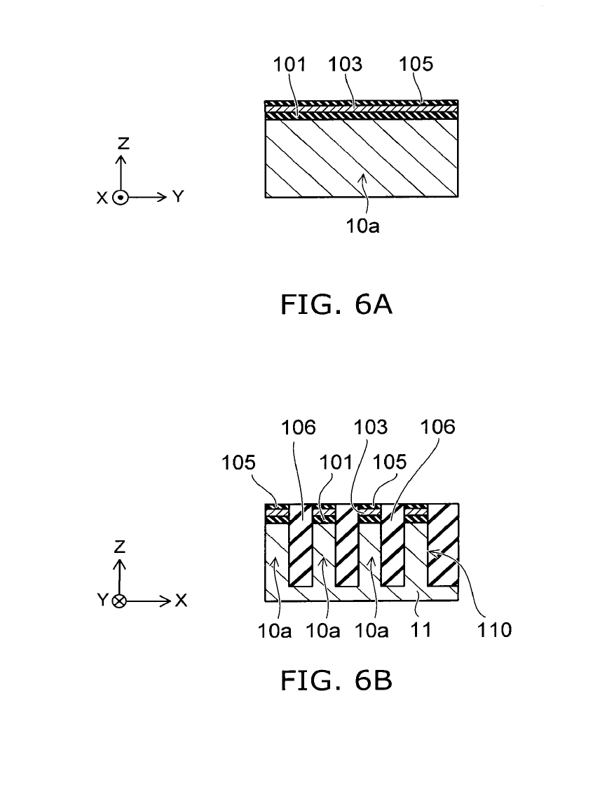

Next, a method for manufacturing the memory cell array 2 according to the first embodiment is described with reference to FIGS. 6A to 10B. FIGS. 6A to 10B are schematic sectional views showing the manufacturing process of the memory cell array 2.

FIGS. 6A and 6B are schematic sectional views showing an insulating film 101, a conductive layer 103, and an insulating film 105 formed on a channel body 10a. FIG. 6A is a cross section taken along line A-A shown in FIG. 2. FIG. 6B is a cross section taken along line B-B shown in FIG. 2.

As shown in FIG. 6A, an insulating film 101, a conductive layer 103, and an insulating film 105 are formed in order on a channel body 10a. The insulating film 101 is, for example, a silicon oxide film. The conductive layer 103 is, for example, a polysilicon layer. The conductive layer 103 is formed on the insulating film 101. The insulating film 105 is, for example, a metal oxide film that has higher permittivity than the insulating film 101. The insulating film 105 is formed on the conductive layer 103. The insulating film 105 is, for example, a hafnium oxide film.

Here, the insulating film 101 and the conductive layer 103 are formed over the memory area MA and a peripheral area thereof. The insulating film 105 is formed in the memory area MA, but not formed in the peripheral area. That is, the insulating film 105 in the peripheral area is removed through the manufacturing process.

As shown in FIG. 6B, the channel body 10a is provided by forming a plurality of trenches 110 in an upper part of a p-type well 11. The p-type well 11 is provided in an underlying layer (for example, silicon substrate) that is not shown in FIG. 6B.

The trenches 110 are formed so that bottom parts thereof are located in the p-type well 11, and divide the insulating film 101, the conductive layer 103, and the insulating film 105. The trenches 110 extend in the Y-direction. Thus, channel bodies 10a of stripe shapes are formed in the upper part of the p-type well 11. The channel bodies 10a are arranged side by side in the X-direction.

Furthermore, an insulating film 106 is embedded inside the trench 110. The insulating film 106 is, for example, a silicon oxide film. The insulating film 106 electrically insulates channel bodies 10a and conductive layers 103 respectively that are adjacent to each other in the X-direction. The trench 110 is provided to have a depth capable of electrically insulating the adjacent channel bodies 10a.

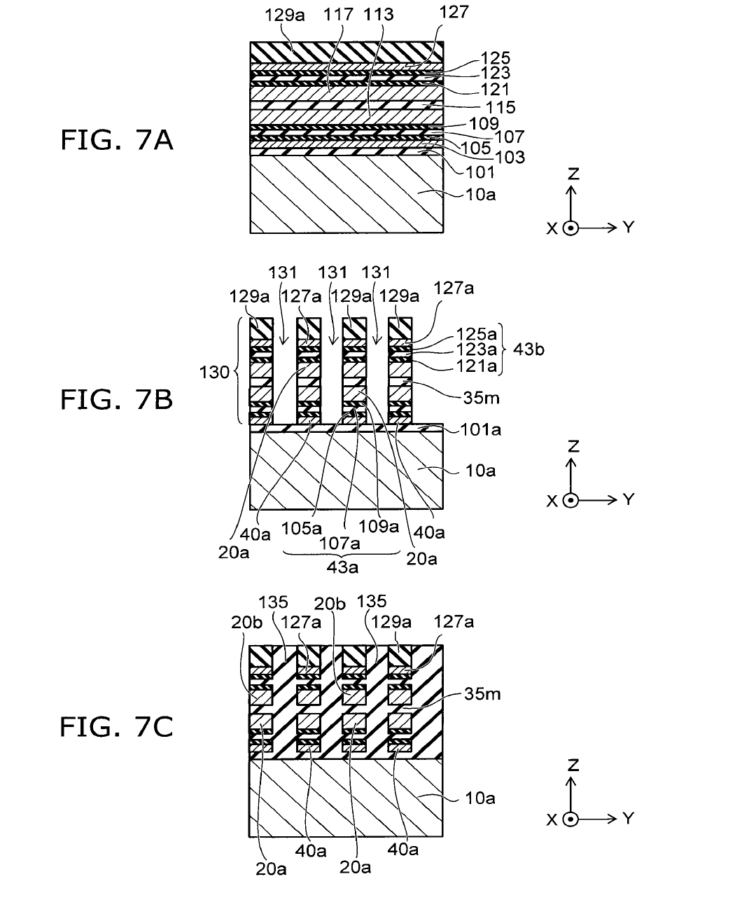

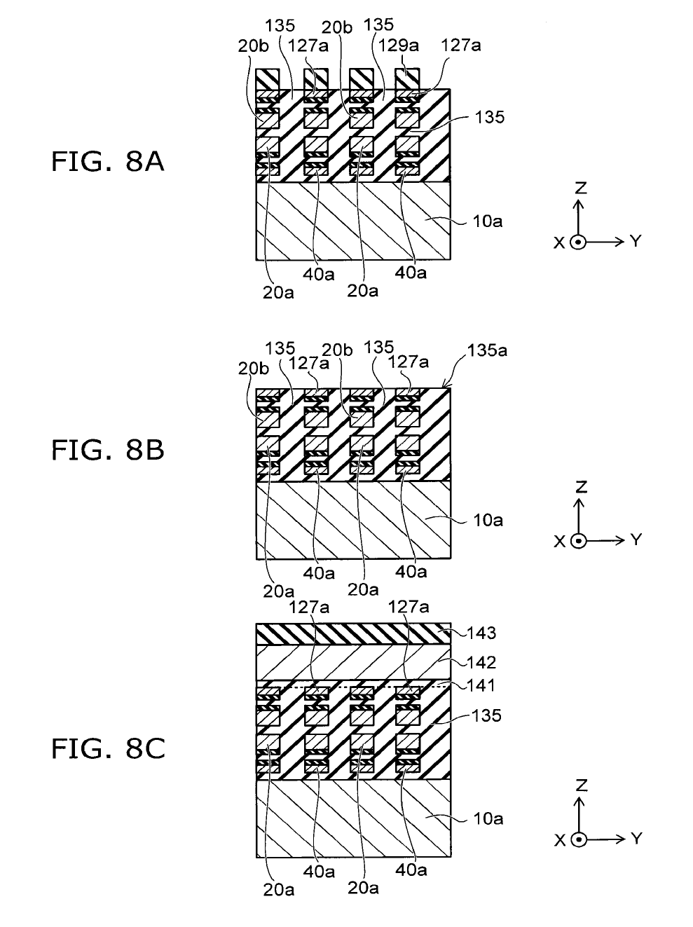

Next, as shown in FIG. 7A, insulating films 107, 109 are formed on the insulating film 105. Here, FIG. 7A and the subsequent FIGS. 7B to 8C are schematic views of a cross section taken along the line A-A shown in FIG. 2.

The insulating film 107 is, for example, a silicon oxide film. The insulating film 109 is, for example, a metal oxide film that has higher permittivity than the insulating film 107. The insulating film 109 is, for example, a hafnium oxide film. The insulating films 107 and 109 are formed in the memory area MA, but not formed in its peripheral area. That is, the insulating films 107 and 109 in the peripheral area are removed through the manufacturing process.

Next, a conductive layer 113 and an insulating film 115 are formed on the insulating film 109. The conductive layer 113 includes, for example, a TiN layer in contact with the insulating film 109, and a tungsten layer formed on the TiN layer. The insulating film 115 is, for example, a silicon oxide film. The insulating film 115 may have an ONO (oxide/nitride/oxide) structure in which a silicon oxide film, a silicon nitride film, and a silicon oxide film are stacked in order.

The conductive layer 113 is formed over the memory area MA and the peripheral area thereof. The insulating film 115 is formed on the entire surface of the memory area MA, but selectively removed in the peripheral area. More specifically, the insulating film 115 is selectively removed in the portion where the transistor element 70 is to be formed.

Next, a conductive layer 117, insulating films 121, 123, 125 and a conductive layer 127 are formed in order on the insulating film 115. The conductive layer 117 includes, for example, a tungsten layer in contact with the insulating film 115, and a TiN layer formed on the tungsten layer. The conductive layer 117 is formed over the memory area MA and the peripheral area thereof.

The insulating film 121 is, for example, a hafnium oxide film. The insulating film 123 is, for example, a silicon oxide film. The insulating film 125 is, for example, a hafnium oxide film. The insulating films 121 and 125 are, for example, a metal oxide film that has higher permittivity than the insulating film 123. The conductive layer 127 is, for example, a polysilicon layer. The insulating films 121, 123, 125 and the conductive layer 127 are formed in the memory area MA, but not formed in the peripheral area thereof.

Furthermore, a mask layer 129 is formed on the conductive layer 127. The mask layer 129 is, for example, a silicon nitride film.

Next, as shown in FIG. 7B, the multilayer body 130 on the channel body 10a is selectively removed by using masks 129a as an etching mask. Thus, grooves 131 are formed to divide the multilayer body. The masks 129a are formed from the mask layer 129 with a stripe shape extending in the X-direction. Thus, the grooves 131 also extend in the X-direction. The grooves 131 are formed to have a depth from the conductive layer 127 to the insulating film 101. In this example, the insulating film 101 is exposed at the bottom surface of the separation groove. However, the insulating film 101 may be divided to expose the channel body 10a.

The conductive layer 103 is divided into a plurality of charge storage layers 40a. The charge storage layers 40a are arranged on the channel body 10a via the insulating film 101. The insulating film 101 between the channel body 10a and the charge storage layer 40a acts as an insulative tunneling layer 41.

The insulating films 105, 107, and 109 are divided into insulating films 105a, 107a, and 109a. The insulative blocking layer 43a is provided on the charge storage layer 40a. The insulative blocking layer 43a includes an insulating film 105a (first film), an insulating film 107a, and an insulating film 109a (second film). The insulating film 105a is provided on a charge storage layer 40a. The insulating films 105a are separated from each other in the X-direction and the Y-direction. The insulating films 107a and the insulating films 109a are formed, for example, into a stripe shape extending in the X-direction.

The conductive layers 113 and 117 are divided into word lines 20a and 20b extending in the X-direction, respectively. The insulating film 115 is divided into insulating layers 35m. The insulating layer 35m is provided between the word line 20a and the word line 20b. The insulating layer 35m extends in the X-direction along the word lines 20a and 20b.

The insulating films 121, 123, 125 and the conductive layer 127 are divided into insulating films 121a, 123a, 125a and conductive layers 127a with a stripe shape extending in the X-direction, respectively. Each insulative blocking layer 43b is formed on a word line 20b, and includes an insulating film 121a (fourth film), an insulating film 123a, and an insulating film 125a.

In the process for forming the grooves 131, a gate electrode 73 of a transistor element 70 and a capacitor element 80, for instance, are formed in the peripheral area around the memory area MA. More specifically, the conductive layers 103, 113, and 117 are formed into a gate electrode 73 in the peripheral section. The conductive layers 103, 113, the insulating film 115, and the conductive layer 117 are formed into a capacitor element 80.

FIG. 7C shows insulating layer 135 embedded inside the grooves 131. The insulating layer 135 is, for example, a silicon oxide layer. An insulating film is formed to cover the multilayer body 130 so that the grooves 131 are filled therewith. Next, by using CMP (chemical mechanical polish), for example, the insulating film is removed, leaving portions embedded in the grooves 131. At this time, the masks 129a may act as a stopper for CMP.

Next, as shown in FIG. 8A, the insulating layer 135 is etched back to expose the wholes of the masks 129a. That is, the insulating layer 135 is removed to the level near the boundary of a mask 129a and a conductive layer 127a.

Next, as shown in FIG. 8B, the masks 129a are removed to expose the conductive layers 127a between the surfaces 135a of the insulating layer 135.

Next, as shown in FIG. 8C, an insulating film 141, a semiconductor layer 142, and a mask layer 143 are stacked in order on the conductive layers 127a and the insulating layer 135. The insulating film 141 is, for example, a silicon oxide film. The insulating film 141 is formed directly on the conductive layers 127a and the insulating layer 135. The semiconductor layer 142 is, for example, a polysilicon layer. The semiconductor layer 142 is provided on the insulating film 141. The mask layer 143 is, for example, a silicon oxide film.

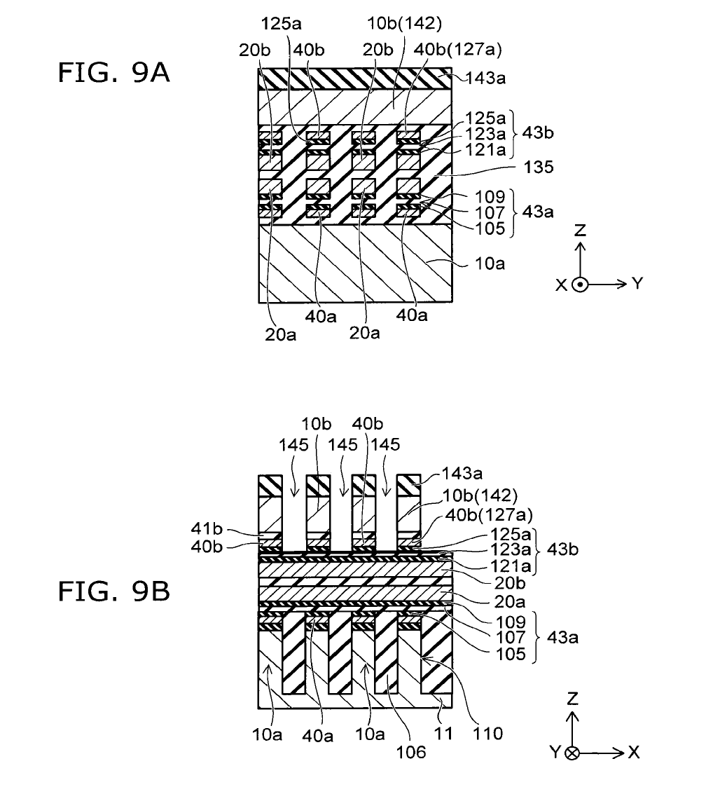

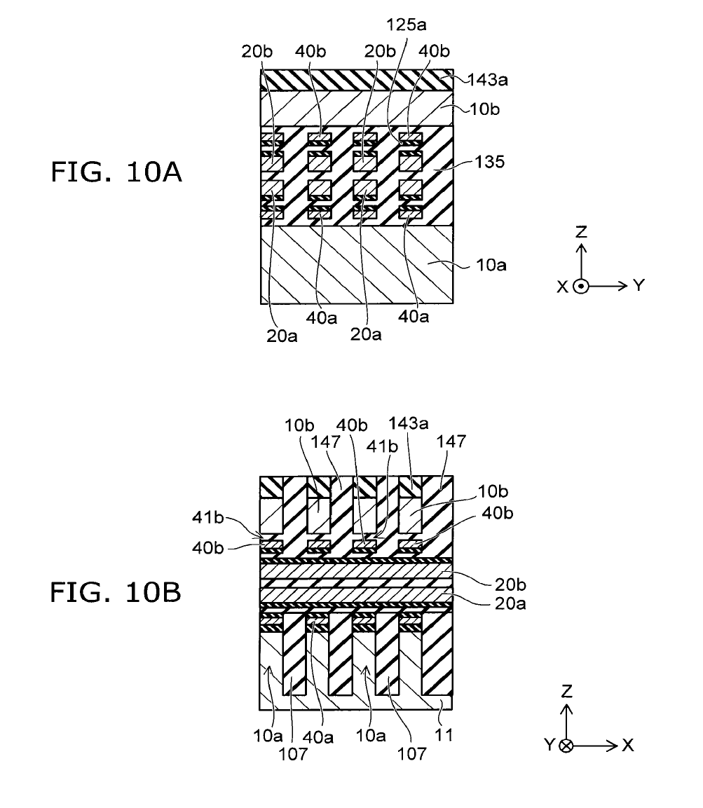

FIGS. 9A and 10A show a cross section taken along line A-A shown in FIG. 2. FIGS. 9B and 10B are a cross section taken along line B-B shown in FIG. 2.

As shown in FIGS. 9A and 9B, the conductive layers 127a and the semiconductor layer 142 are selectively removed by using masks 143a. Thus, grooves 145 are formed. The masks 143a are formed by dividing the mask layer 143 into stripes. The masks 143a extend in the Y-direction.

The grooves 145 divide the conductive layer 142, the insulating film 141, the conductive layers 127a, and the insulating films 125a. The separation grooves 145 expose the insulating films 123a at a bottom surface thereof. The conductive layers 127a and the semiconductor layer 142 are divided into charge storage layers 40b and channel bodies 10b, respectively. The insulating films 125a and charge storage layers 40b are formed to be separated from each other in the X-direction and the Y-direction.

An insulative blocking layer 43b includes an insulating film 125a (third film), an insulating film 123a, and an insulating film 121a (fourth film). The insulating films 121a extend in the X-direction and are arranged side by side in the Y-direction. For instance, the insulating films 123a may extend in the X-direction. Alternatively, the insulating films 123a may also be separated from each other in the X-direction.

Next, as shown in FIGS. 10A and 10B, insulating films 147 are formed to be embedded in the grooves 145. The insulating films 147 are, for example, a silicon oxide film. Although the foregoing manufacturing process has been described with reference to a portion of memory cells MC, it is understood that the select transistors STD and STS are also formed simultaneously with the memory cells MC. For instance, the insulating film 115 is divided into insulating layers 35m, each of which separates a word line 20a and a word line 20b. Simultaneously, the insulating film 115 is also divided into insulating layers 35s between the select transistors STD1 and STD2, and between the select transistors STS1 and STS2.

In general, as the degree of integration of the memory cell array becomes higher, the spacing between the adjacent memory cells MC becomes narrower, and the line width of the word line also becomes narrower. Thus, a method of forming interconnections, which requires multiple steps, such as the sidewall method is used to form word lines and memory cells MC. This complicates the manufacturing process of a three-dimensional memory cell array, increasing the manufacturing cost thereof. In contrast, in the embodiment, the word lines 20a and 20b can be collectively formed by forming grooves 131 e.g. in the step shown in FIG. 7B. This can simplify the manufacturing process, and reduces the manufacturing cost.

The gate electrode 73 and electrodes 85, 89 of the transistor element 70 and the capacitor element 80 around the memory area MA include the conductive layers 113 and 117 that constitute the word lines 20. The conductive layers 113 and 117 have a larger thickness among the insulating films and conductive films stacked on the channel body 10a. Thus, in the embodiment, a step difference of the wafer surface can be reduced between the memory area MA and the peripheral area thereof by providing the conductive layers 113 and 117 in the peripheral area. This makes fine processing easier in a step for forming memory cells MC, and improves a manufacturing yield.

Furthermore, it is also possible to improve the properties of the insulative blocking layer 43 between the word line 20 and the charge storage layer 40. For instance, the insulative blocking layer 43 may include a first film and a second film made of metal oxide film. In such a case, the first films each in contact with the charge storage layer 40 are preferably formed to be separated from each other in the X-direction and the Y-direction. This may suppress a charge movement between the adjacent memory cells and improve the charge retention characteristics thereof. The second film can be formed so as to extend along the word line 20. This may increase capacitive coupling between the word line 20 and the charge storage layer 40, and improves the data write and erasure characteristics in the memory cell MC.

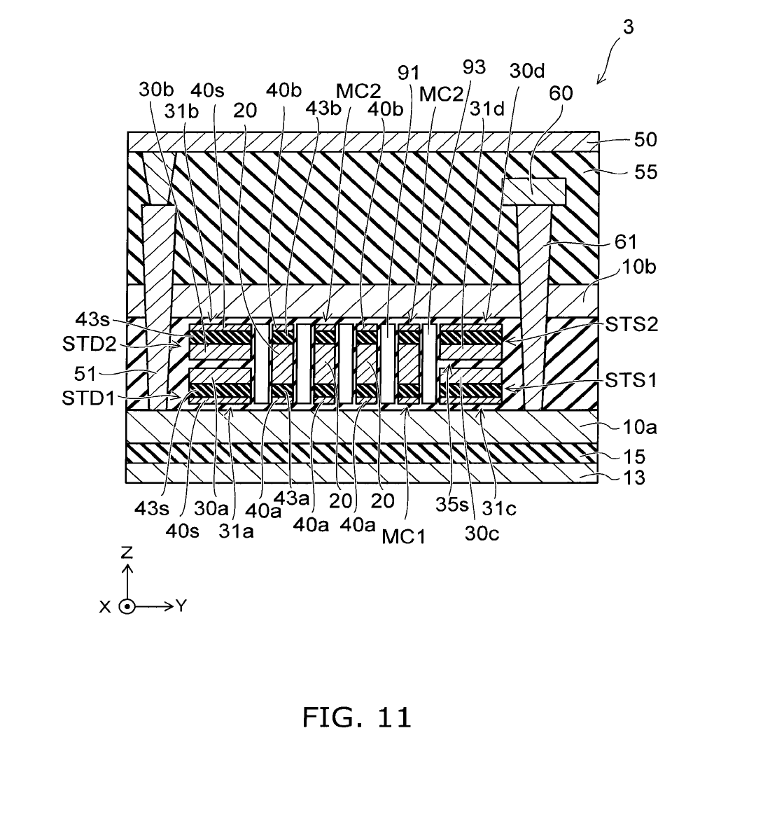

FIG. 11 is a schematic sectional view showing a memory cell array 3 according to another variation of the first embodiment. The memory cell array 3 includes a third insulating layer (hereinafter, insulating layer 15) between the underlying layer 13 and the channel body 10a. The memory cell array 3 can be formed by using a wafer having SOI (silicon on insulator) structure, for example.

The underlying layer 13 is e.g. a silicon wafer. The insulating layer 15 is, for example, a silicon oxide film. The insulating layer 15 is provided on the underlying layer 13. The channel body 10a is formed on the insulating layer 15 by dividing a silicon layer into stripes.

The memory cell array 3 includes a channel body 10b stacked on the channel body 10a in the Z-direction. The memory cell array 3 includes memory cells MC1 and memory cells MC2 between the channel body 10a and the channel body 10b. The memory cell MC1 includes a charge storage layer 40a. The memory cell MC2 includes a charge storage layer 40b. The memory cells MC1 and MC2 share the word line 20.

The memory cell array 3 includes a contact plug 51 extending in the Z-direction. The contact plug 51 electrically connects the channel body 10a to the channel body 10b. The memory cell array 3 includes a select transistor STD between the contact plug 51 and the memory cells MC.

Furthermore, the memory cell array 3 includes a contact plug 61 extending in the Z-direction. The contact plug 61 electrically connects the channel body 10a to the channel body 10b. The memory cell array 3 includes a select transistor STS between the contact plug 61 and the memory cells MC.

In this example, the silicon layer provided on the insulating layer 15 is divided into the channel bodies 10a of the stripe shape. This ensures electrical insulation between the channel bodies 10a arranged side by side in the X-direction. That is, there is no need to form a deep trench 110 as shown in FIG. 6B. This facilitates the manufacturing process.

Furthermore, as shown in FIG. 11, the memory cell array 3 may include gaps 91 between two adjacent word lines 20. The memory cell array 3 may include gaps 93 between the each of the select transistors STS and STD and memory cells MC. The gaps 91, 93 reduce the parasitic capacitances between the two adjacent memory cells MC, and the parasitic capacitances between each of the select transistors STS, STD and the memory cells MC. This may also reduce a coupling ratio of a capacitance between a word line 20 and a charge storage layer 40 to a capacitance between the charge storage layer 40 and a channel body 10, reducing voltages applied to the memory cells MC for data writing and erasing. The gaps 91, 93 may be not only provided in this example, but also provided in the memory cell arrays 1, 2 shown in FIGS. 3 and 4.

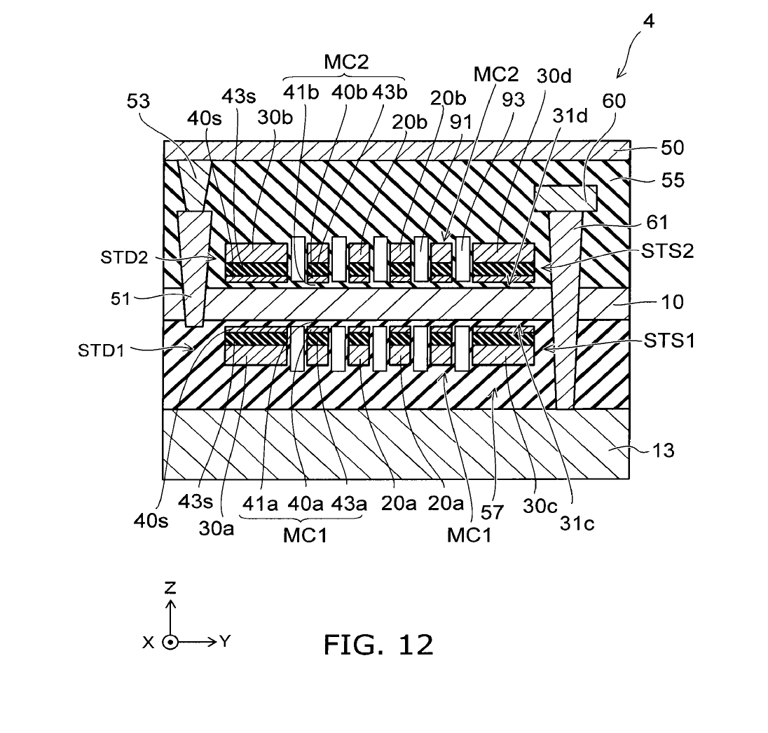

FIG. 12 is a schematic sectional view showing a memory cell array 4 of a non-volatile memory device according to a second embodiment. The memory cell array 4 includes an underlying layer 13, a channel body 10, word lines 20a, and word lines 20b.

The channel body 10 is, for example, a polysilicon layer of a stripe shape. The channel body 10 extends along the underlying layer 13 in the Y-direction. The underlying layer 13 is, for example, a semiconductor substrate such as a silicon wafer.

The word lines 20a are provided between the underlying layer 13 and the channel body 10. The word lines 20a extend along the underlying layer 13 in the X-direction. The word lines 20b are provided on a side of the channel body 10 opposite to the word lines 20a. The word lines 20b extend in the X-direction. That is, the channel body 10 extends in the Y-direction between a word line 20a and a word line 20b.

A memory cell MC1 is provided at an intersecting portion of a word line 20a and the channel body 10. The memory cell MC1 is provided on the underlying layer 13 via an insulating layer 57. The memory cell MC1 includes a charge storage layer 40a, an insulative tunneling layer 41a, and an insulative blocking layer 43a.

A memory cell MC2 is provided between a word line 20b and the channel body 10. The memory cell MC2 includes a charge storage layer 40b, an insulative tunneling layer 41b, and an insulative blocking layer 43b. The memory cell MC2 shares the channel body 10 with the memory cell MC1.

The memory cell array 4 further includes a bit line 50 and a source line 60. The bit line 50 is provided on the memory cell MC2 via an insulating layer 55. The bit line 50 extends in the Y-direction that is a same direction as the extending direction of the channel body 10. The source line 60 extends in the X-direction in the insulating layer 55.

The memory cell array 4 includes contact plugs 51, 53, and 61. The bit line 50 is electrically connected to the channel body 10 via the contact plugs 51 and 53. The source line 60 is electrically connected to the channel body 10 via the contact plug 61.

A select transistor STD2 is provided between the contact plug 51 and memory cells MC2. A select transistor STS2 is provided between the contact plug 61 and the memory cells MC2. The contact plug 51 is electrically connected to the drain of the select transistor STD2, which is a part of the channel body 10. The contact plug 61 is electrically connected to the source of the select transistor STS2, which is other part of the channel body 10.

The memory cell array 4 includes a select transistor STD1 on a side of the channel body 10 opposite to the select transistor STD2. The memory cell array 4 includes a select transistor STS1 on a side of the channel body 10 opposite to the select transistor STS2.

That is, the select transistor STD1 and the select transistor STD2 share the channel body 10. The channel body 10 extends between the select transistor STD1 and the select transistor STD2. The select transistor STS1 and the select transistor STS2 share the channel body 10. The channel body 10 extends between the select transistor STS1 and the select transistor STS2.

In the embodiment, a memory cells MC1 and MC2 disposed in the Z-direction share the channel body 10. Thus, the step of dividing a semiconductor layer into channel bodies of a stripe shape is eliminated comparing with the memory cell array including channel bodies 10a and 10b. Furthermore, the channel body 10 is provided on the underlying layer 13 via the insulating layer 57. Thus, there is no need to form a trench 110 shown in FIG. 6B. This facilitates the manufacturing process thereof.

Furthermore, as shown in FIG. 12, the memory cell array 4 may include gaps 91, 73 between two adjacent memory cells MC in the X-direction and between each of the select transistors STS, STD and the memory cells MC. Thus, the voltages applied to the memory cell MC may be decreased when writing or erasing data.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A non-volatile memory device comprising:
a first semiconductor body extending in a first direction;
a second semiconductor body arranged side by side with the first semiconductor body and extending in the first direction;
a first electrode between the first semiconductor body and the second semiconductor body and extending in a second direction crossing the first direction;
a first charge storage layer between the first electrode and the first semiconductor body; and
a second charge storage layer between the first electrode and the second semiconductor body.

2. The device according to claim 1, further comprising:
a first insulative tunneling layer between the first semiconductor body and the first charge storage layer;
a first insulative blocking layer between the first charge storage layer and the first electrode,
a second insulative tunneling layer between the second semiconductor body and the second charge storage layer; and
a second insulative blocking layer between the second charge storage layer and the first electrode.

3. The device according to claim 2, wherein the first insulative blocking layer and the second insulative blocking layer include a metal oxide having a higher permittivity than the permittivities of the first insulative tunneling layer and the second insulative tunneling layer.

4. The device according to claim 1, further comprising:
a plurality of first charge storage layers arranged side by side in the second direction along the first electrode, the plurality of first charge storage layers including the first charge storage layer; and
a plurality of second charge storage layers arranged in the second direction along the first electrode, the plurality of second storage layers including the second charge storage layer, wherein
the first insulative blocking layer includes first films arranged in the second direction and a second film extending in the second direction, the first films each being provided between the second film and each of the plurality of first charge storage layers, and the second film extending between the first electrode and each of the first films; and
the second insulative blocking layer includes third films arranged in the second direction and a fourth film extending in the second direction, the third films each being provided between the fourth film and each of the plurality of second charge storage layers, and the fourth film extending between the first electrode and each of the third films.

5. The device according to claim 1, further comprising:
a first conducting body electrically connecting the first semiconductor body to the second semiconductor body;
a first selecting electrode between the first electrode and the first conducting body; and
a second selecting electrode stacked on the first selecting electrode; and
a first insulating layer between the first selecting electrode and the second selecting electrode.

6. The device according to claim 5, further comprising a second insulating layer provided in the first electrode, wherein the first electrode includes a first portion on the first charge storage layer and a second portion stacked on the first portion via the second insulating layer.

7. The device according to claim 6, wherein the first insulating layer and the second insulating layer are one of a silicon oxide layer, a silicon oxide layer and a multi-layer that includes a silicon oxide film and a silicon nitride film, or a combination thereof.

8. The device according to claim 5, further comprising:
a second conducting body electrically connecting the first semiconductor to the second semiconductor;
a first interconnection extending in the first direction and electrically connected to the first conductor; and
a second interconnection extending in the second direction and electrically connected to the second conductor,
wherein the first electrode is provided between the first conducting body and the second conducting body.

9. The device according to claim 5, further comprising:
a second electrode between the first electrode and the first selecting electrode; and
a third charge storage layer between the second electrode and the first semiconductor body,
wherein a first distance between the second electrode and the first selecting electrode is wider than a second distance between the first electrode and the second electrode, and a difference between the first distance and the second distance is 10 nanometers or less.

10. The device according to claim 2, wherein the first electrode includes one of titanium nitride, tantalum nitride, tungsten nitride, p-type polysilicon, and n-type polysilicon in a first portion adjacent to the first insulative blocking layer and in a second portion adjacent to the second insulative blocking layer.

11. The device according to claim 1, wherein the first charge storage layer and the second charge storage layer include one of polysilicon, titanium nitride, and tantalum nitride.

12. The device according to claim 1, wherein the first charge storage layer and the second charge storage layer include a silicon nitride film.

13. The device according to claim 6, further comprising:
a transistor element provided around a memory area including the first charge storage layer and the second charge storage layer, the transistor element including a third semiconductor body, a gate insulating film provided on the third semiconductor body, and a gate electrode provided on the gate insulating film; and
a capacitor element provided around the memory area and including a third electrode, a dielectric film provided on the third electrode, and a fourth electrode provided on the dielectric film.

14. The device according to claim 13, wherein
The gate electrode includes a same material as the first electrode, and
the gate electrode has a thickness in the second direction that is same as total thickness in the second direction of the first portion and the second portion in the first electrode.

15. The device according to claim 13, wherein
the third electrode includes a same material as the first portion of the first electrode,
the fourth electrode includes a same material as the second portion of the first electrode, and
the dielectric film includes a same material as the first insulating layer.

16. The device according to claim 1, further comprising:
a third insulating layer, the first semiconductor body provided on the third insulating layer.

17. A non-volatile memory device comprising:
an underlying layer;
a semiconductor body extending along the underlying layer in a first direction;
a first electrode provided between the underlying layer and the semiconductor body and extending along the underlying layer in a second direction crossing the first direction;
a second electrode extending in the second direction, the semiconductor body provided between the first electrode and the second electrode;
a first charge storage layer between the first electrode and the semiconductor body; and
a second charge storage layer between the second electrode and the semiconductor body.

18. The device according to claim 17, further comprising:
a first interconnection extending in the first direction;
a first conducting body electrically connecting the first interconnection to the semiconductor body;
a second interconnection extending in the second direction; and
a second conducting body electrically connecting the second interconnection to the semiconductor body,
wherein one of the first charge storage layer and the second charge storage layer is disposed between the first conducting body and the second conducting body.

19. The device according to claim 18, further comprising:
a first selecting electrode extending in the second direction between the first conducting body and the one of the first charge storage layer and the second charge storage layer; and
a second selecting electrode extending in the second direction, the semiconductor body being provided between the first selecting electrode and the second selecting electrode.
